(19) United States
(12) Patent Application Publication
(10) Pub. No.: US 2019/0223308 A1
(43) Pub. Date: Jul. 18, 2019

(54) USE OF A MULTI-START SCREW THREAD IN AN EX-D HOUSING

(71) Applicant: Endress+Hauser GmbH+Co. KG, Maulburg (DE)

(72) Inventors: Andreas Krumbholz, Maulburg (DE); Robert Schmidt, Schopfheim (DE)

(21) Appl. No.: 16/359,850

(22) Filed: Mar. 20, 2019

Related U.S. Application Data
(63) Continuation of application No. 15/567,821, filed on Oct. 19, 2017, now abandoned.

(30) Foreign Application Priority Data
Apr. 24, 2015 (DE) 10 2015 106 350.6

(51) Int. Cl. H05K 5/02; H05K 7/14; G01D 11/24

(52) U.S. Cl. CPC H05K 5/0239; G01D 11/24; H05K 7/1462

(57) ABSTRACT

The present disclosure relates to a field device of automation technology, including a housing with an opening for accommodating field device components, wherein the housing has at an edge of the opening a first screw thread, a lid for closing the opening of the housing, wherein the lid has at an edge of the lid a second screw thread, wherein the first and second screw threads are embodied to be complementary to one another, so that the housing after closing with the lid in assembly fulfills all Ex-d requirements, wherein the first and second screw threads are embodied as multi-start threads.

### CROSS-REFERENCE TO RELATED APPLICATION

The present continuation-in-part application is related to and claims the priority benefit of German Patent Application No. 10 2015 106 350.6, filed on Apr. 24, 2015, International Patent Application No. PCT/EP2016/056592 filed on Mar. 24, 2016, and U.S. patent application Ser. No. 15/567,821 filed on Oct. 19, 2017, the entire contents of which are incorporated herein by reference.

### TECHNICAL FIELD

The invention relates to a field device of automation technology, comprising a housing and a lid for closing the housing, wherein the housing after closing by means of the lid fulfills all Ex-d requirements.

### BACKGROUND

In automation technology, as in process and manufacturing automation technology, field devices are often employed for registering and/or influencing process variables. Serving for registering process variables are sensors, such as, for example, fill level measuring devices, flow measuring devices, pressure- and temperature measuring devices, pH-redox potential measuring devices, conductivity measuring devices, etc., which register the corresponding process variables, fill level, flow, pressure, temperature, pH-value, and conductivity. Serving for influencing process variables are actuators, such as, for example, valves or pumps, via which the flow of a liquid in a pipeline section or the fill level in a container can be changed. Referred to as field devices are, in principle, all devices, which are applied near to the process and which deliver, or process, process relevant information. In connection with the invention, referred to as field devices are also remote I/Os, radio adapters, and, in general, devices, which are arranged at the field level and communicate via a data bus with one another. Often, also network components are considered to be field devices. A large number of such field devices or network components are produced and sold by the firm, Endress+Hauser.

Field devices commonly have a housing for accommodating an electronics unit and a sensor unit. Such a housing may be pot-shaped body with a lid and may be manufactured of a non-conductive material. Often used as materials are plastics and composite materials. The housing can, however, also be made of a metal or a metal alloy. Conventionally, a housing of a fill-level measuring device may be composed of 60% aluminum, 25% polymer and 15% stainless steel, and a housing of a pressure measuring device may be composed only of aluminum and stainless steel but no polymer.

In applications, field devices must be operated in locations that are exposed to a risk of explosion, for example, filling stations and chemical plants where explosive gases can form. Devices that are usable in explosion-prone areas must comply with very strict safety requirements. Said requirements include preventing or avoiding spark formation, which could potentially trigger an explosion, and containing an explosion within the field device such that the device does not cause an explosion in its surroundings, since a spark that occurs inside an enclosed volume can still have an impact on the surroundings outside the enclosed volume. Explosion protection measures are subdivided into ignition protection classes that are regulated in the respective industry standards, as in, for example, the series of standards IEC 60079 of the International Electrotechnical Commission, including “Explosive atmospheres—Part 1: Equipment protection by flameproof enclosures ‘d’,” IEC 60079-1. Further such standards include “Explosion-Proof Enclosures for Use in Class I Hazardous Locations,” CSA Standard C22.2 No. 30-M1986 and “Approval Standard for Explosionproof Electrical Equipment General Requirements,” Class Number 3615.

The ignition protection class that is particularly relevant for measuring devices in practice is “inherent safety (Ex-i).” Within this class, the values for the existing electrical energy, reflected particularly in the electrical quantities of current, voltage, and power, must be below a preset limit value inside the device at all times. The limit values are selected such that in the event of a failure, e.g., a short-circuit, the maximum released energy is not sufficient to create an ignition spark or a dangerous overheating.

In cases where energy cannot be limited to inherently safe values, additional ignition protection measures of other ignition protection classes must be applied, e.g., ignition protection measures of the ignition protection class “explosion protection, pressure-resistant encapsulation (Ex-d),” the ignition protection class “encapsulation (Ex-m),” or the ignition protection class “powder filling (Ex-q).”

In general, conventional field device housings meeting explosion protection, pressure-resistant encapsulation (Ex-d), also referred to as explosion-proof or flameproof in certain regions, standards include a single-start metric thread, e.g., m80×1.5, to enable a releasable connection between an Ex-d housing and an Ex-d lid. A device according to the Ex-d standard, for example, requires at least seven engaged screw threads to assure flame penetration resistance over a gap length, which is axial length of a joint of the housing assembly. The gap length must be sufficiently long and with a gap (i.e., interstice) narrow enough to guarantee the cooling of the flue gases for an explosion within the device housing. Thus, a minimum axial thread length is needed to provide suitable flame penetration resistance over the gap length for a given housing/lid combination to meet the Ex-d requirement. With extra length for chamfer and thread runout, the thread length may be about 13.5 mm (7×1.5 mm+3 mm extra), which, in practice, means about eight revolutions of the lid. This is not optimal for the internal assembly of the field device components and the maintenance of the field device, since it is, on the one hand, time consuming and, on the other hand, ergonomically unfavorable in requiring too much twisting motion.

Accordingly, there remains a need for further contributions in this area of technology.

### SUMMARY

An aspect of the present disclosure is to provide a field device of automation technology that fulfills the Ex-d requirements and, yet, can be rapidly screwed open and closed. This aspect of the present disclosure includes a field device of automation technology, comprising a housing with an opening for accommodating field device components, wherein the housing has at an edge of the opening a first screw thread, a lid for closing the opening of the housing, wherein the lid has at an edge of the lid a second screw thread, wherein the first and second screw threads are embodied to be complementary to one another, so that the housing after closing with the lid fulfills all Ex-d requirements, wherein that the first and second screw threads are embodied as multi-start screw threads.

In an embodiment, the first and second screw threads are embodied as a four-start screw thread.

In a further embodiment, the first and second screw threads have axially at least five, preferably eight, crests along the gap length formed by the first and second screw threads.

Another aspect of the present disclosure is likewise achieved through the use of a multi-start thread in a lid-closing mechanism of an Ex-d requirements fulfilling housing of a field device of automation technology.

### BRIEF DESCRIPTION OF THE DRAWINGS

The invention will now be explained in greater detail based on the appended drawing, the figures of which show as follows:

FIG. 1 shows a longitudinal section of a housing of a field device of automation technology according to the state of the art;

FIG. 2 shows a front view of a lid of the invention with four screw threads extending in parallel to form a four-start screw thread for a housing with a four-start screw thread; and

FIG. 3 shows a front view of a lid and cross-section of a housing with multi-start with two starts.

### DETAILED DESCRIPTION

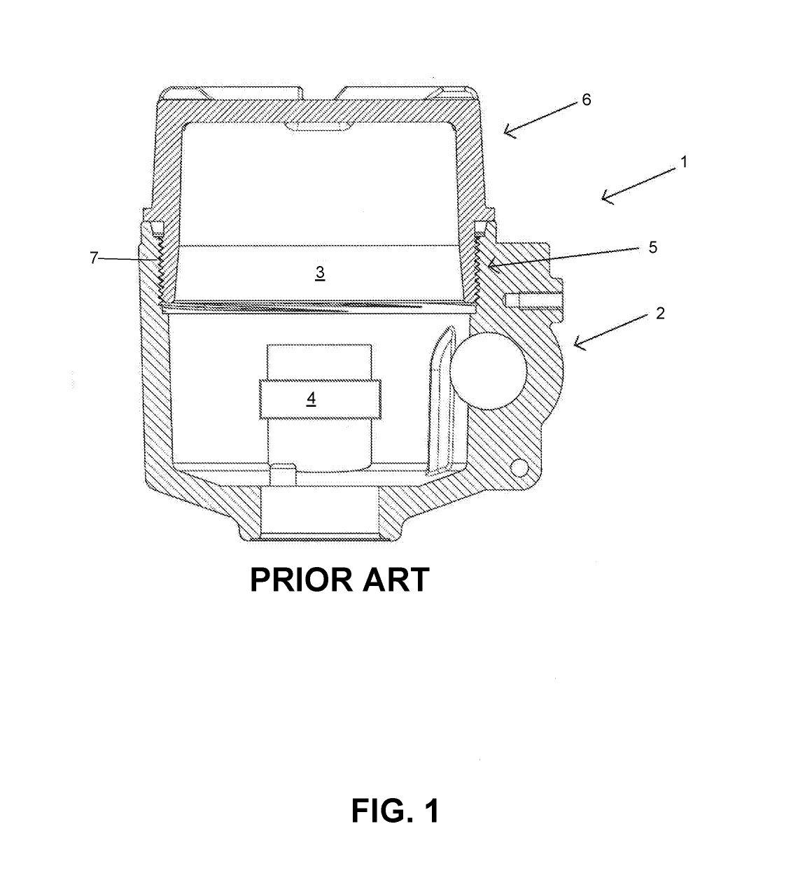

FIG. 1 shows a longitudinal section of a field device 1 of automation technology according to the state of the art. The field device 1 includes a housing 2 and a lid 6. The housing 2 and the lid 6 are each pot-shaped. The housing 2 is embodied to accommodate field device components 4 and includes, for this purpose, an opening 3. The housing 2 includes in an outer edge region that defines the opening 3. The housing 2 further includes a first screw thread 5 in the outer edge region. The lid 6 includes a second screw thread 7 in an outer edge region that defines an opening of the lid 6. The first screw thread 5 and second screw thread 7 are both single-start threads and are complementary to one another. The housing 2 and the lid 6 may be configured such that, when assembled together, conventional field device 1 may meet all explosion-proof, flameproof requirements. However, because the first screw thread 5 and the second screw thread 7 are both single-start threads, relatively many turns (e.g., revolutions) of the lid 6 to the housing 2 are needed to provide suitable flame penetration resistance over the gap length formed by the housing/lid combination to meet the Ex-d requirement. Consequently, many revolutions of the lid 6 are required to assemble the lid 6 to the housing 2 such that the assembly meets the Ex-d requirements.

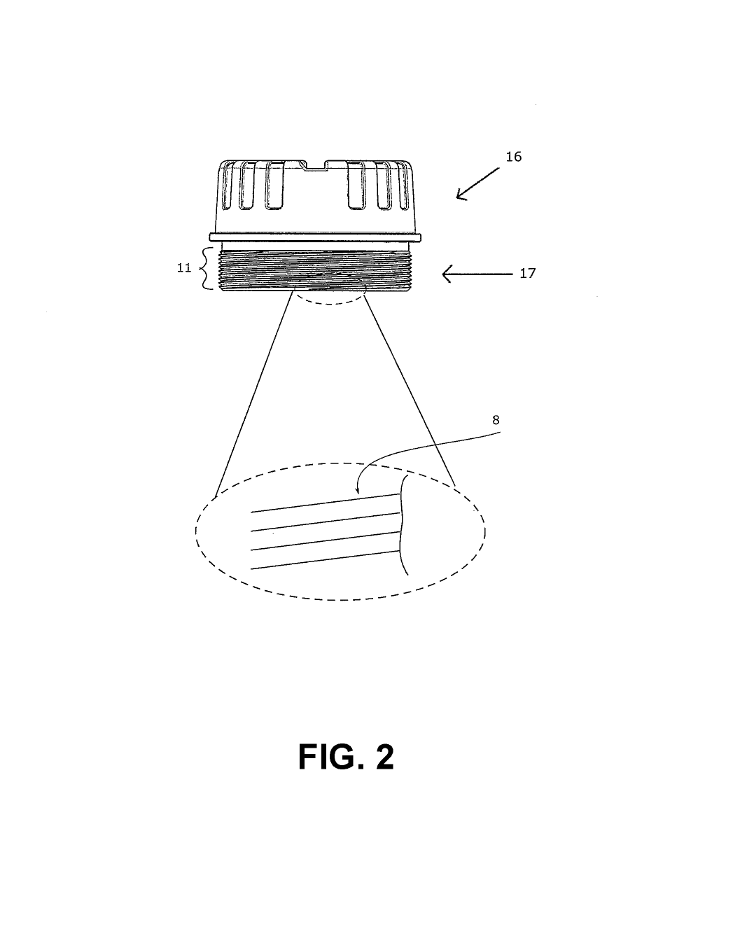

FIG. 2 shows a front view of a lid 16 for a housing 12 of the present disclosure. The lid 16 includes a lid screw thread 17 configured as a multi-start thread and having an axial thread length 11. A multi-start thread consists of two or more intertwined threads running parallel to one another. Intertwining threads allow the lead distance of a thread to be increased without changing its pitch. A double-start thread will have a lead distance twice that of a single-start thread of the same pitch, a triple-start thread will have a lead distance three times longer than a single-start thread of the same pitch, and so on. By maintaining a constant pitch, a depth of the thread, measured from crest to root, will also remain constant. This geometry enables multi-start threads to maintain a shallow thread depth relative to their longer lead distance. Another advantage of a multi-start thread is that more contact surface is engaged in a single thread rotation.

The multi-start thread of the lid screw thread 17 may be a four-start thread 8, as shown in the detail view of FIG. 2. In such an embodiment, the lid screw thread 17 may have at least eight thread crests over the axial thread length 11. In another embodiment, the axial length 11 may be configured such that the lid screw thread 17 may have at least five thread crests over the axial thread length 11. In alternative embodiments, a lid screw thread 17 may have more or fewer starts, for example, eight starts.

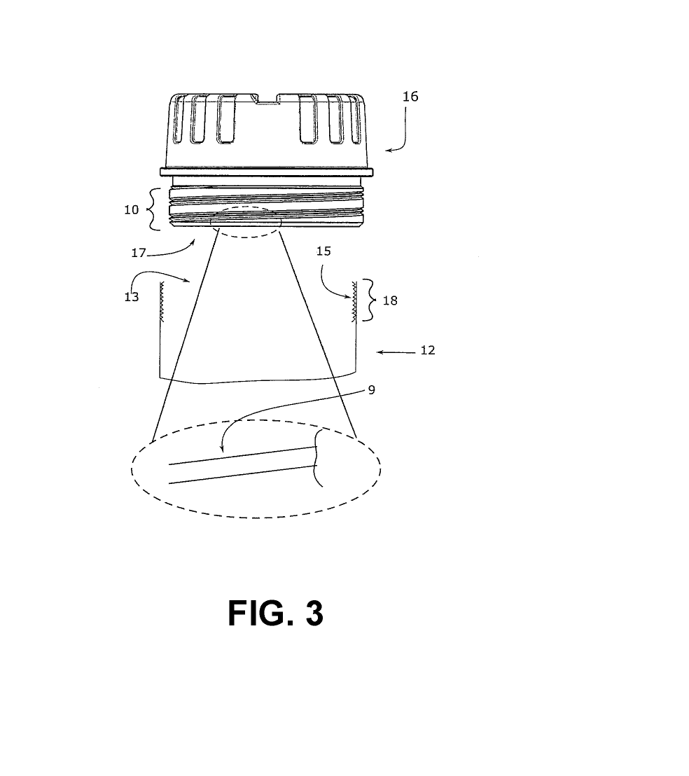

FIG. 3 shows an exploded view with front view of an embodiment of the lid 16 and a cross-sectional view of a housing 12, each embodied to meet the Ex-d industry requirements in assembly. An embodiment of the lid 16 may include the lid screw thread 17 with a two-start thread 9, as shown in the detail. Such an embodiment of the lid screw thread 17 is complementary to a housing screw thread 15 of a housing 12 formed at an edge of an opening 13 in the housing 12, which housing screw thread 15 is also multi-start. Being complementary to the lid screw thread 17, the housing screw thread 15 may also be a two-start thread. In alternative embodiments, the housing screw thread 15 and the lid screw thread 17 may have more starts yet remain complementary.

In an embodiemnt, the lid screw thread 17 of the lid 16 and the complementary housing screw thread 15 of the housing 12 may have axially at least five thread crests 10. When the housing 12 is assembled to the lid 16, thereby closing the opening 13, the housing screw thread 15 and lid screw thread 17 define a gap length 18, as shown in FIG. 3. In such assembly, the gap length 18 is configured to provide adequate flame penetration resistance to meet the Ex-d requirements, thereby forming an explosion-proof, flameproof encapsulation for the field device. In at least one embodiment, the pitch of complementary the housing screw thread 15 and lid screw thread 17 may be greater than conventional Ex-d housing assemblies, such as those shown in FIG. 1. By running individual thread starts in parallel with increased pitch, the number of revolutions needed to assemble the housing 12 to the lid 16 to form the explosion-proof, flameproof encapsulation is reduced, thus enabling a faster assembly operation with fewer revolutions. Further, the increased slope of the housing screw thread 15 and lid screw thread 17 at equal tightening torque generates less pre-stress in the assembly joint, which, in turn, allows the lid 16 to be opened more easily. At the same time, the gap length 18 for the flame penetration resistance, and for ignition sparks, may remain the same.

1. A field device of automation technology, comprising:
a housing configured to accommodate field device components, wherein the housing includes an opening in a side of the housing and, at an edge of the opening, a first screw thread in an axial direction; and
a lid configured to close the opening of the housing in assembly with the housing, wherein the lid includes a side wall defining a second screw thread in the axial direction from an edge of the lid,
wherein the first screw thread and the second screw thread are complementary to each other and define a gap length in the axial direction having a flame propagation resistance over the gap length such that the assembly of the housing and lid meet the requirements for explosion protection by explosion-proof and/or flameproof encapsulation as defined by an Ex-d industry standard, and
wherein the first screw thread and the second screw thread are each configured as multi-start threads having two or more intertwined threads running in parallel to one another.

2. The field device of claim 1, wherein the first screw thread and the second screw thread are each embodied as four-start threads.

3. The field device of claim 1, wherein the first screw thread and the second screw thread have axially at least five thread crests.

4. The field device of claim 1, wherein the first screw thread and the second screw thread have axially at least eight thread crests.

5. A lid-closing mechanism of a field device of automation technology, comprising:
a housing configured to house field device components, the housing including an opening in a housing wall, the opening having an edge from which a first screw thread extends along the wall in an axial direction; and
a lid adapted to close the opening of the housing in assembly with the housing, the lid including a side wall having an edge from which a second screw thread extends along the side wall in the axial direction,
wherein the first screw thread and the second screw thread are complementary and define a gap length of the opening such that, when the opening is closed by the lid, the field device fulfills requirements of flame propagation resistance over the gap length according to requirements for explosion protection by explosion-proof and/or flameproof encapsulation as defined in Ex-d industry standard IEC 60079-1, and
wherein the first screw thread and the second screw thread are each multi-start screw threads having two or more intertwined threads running in parallel to one another.

6. The lid-closing mechanism of claim 5, wherein the first screw thread and the second screw thread are embodied as four-start threads.

7. The lid-closing mechanism of claim 5, wherein the first screw thread and the second screw thread have axially at least five thread crests.

8. The lid-closing mechanism of claim 5, wherein the first screw thread and the second screw thread have axially at least eight thread crests.
